(19) United States
(12) Patent Application Publication
(10) Pub. No.: US 2016/0291486 A1
(43) Pub. Date: Oct. 6, 2016

(54) IMPRINTING APPARATUS, METHOD OF CREATING DATA ON MATERIAL DISTRIBUTION, IMPRINTING METHOD, AND ARTICLE MANUFACTURING METHOD

(71) Applicant: CANON KABUSHIKI KAISHA, Tokyo (JP)

(72) Inventors: Tomomi Funayoshi, Utsunomiya-shi (JP); Takuro Yamazaki, Utsunomiya-shi (JP); Masayoshi Fujimoto, Utsunomiya-shi (JP); Hiromitsu Yamaguchi, Yokohama-shi (JP)

(21) Appl. No.: 15/082,985

(22) Filed: Mar. 28, 2016

(30) Foreign Application Priority Data
Mar. 31, 2015 (JP) 2015-074495

(51) Int. Cl. G03F 9/00; G03F 7/00

(52) U.S. Cl. CPC G03F 9/7034; G03F 7/0002

(57) ABSTRACT

Provided is an imprinting apparatus that forms patterns sequentially on a plurality of areas of a substrate by using a mold and imprint material. The apparatus includes a moving unit configured to be movable along a horizontal plane while carrying the substrate on which the imprint material is provided, and an applying unit configured to apply the imprint material onto the substrate based on information related to a state of the imprint material and information related to an order of pattern formation, the information related to the state of the imprint material varying with the movement of the moving unit.

### BACKGROUND OF THE INVENTION

1. Field of the Invention

The present invention relates to an imprinting apparatus, a method of creating data on material distribution, an imprinting method, and an article manufacturing method.

2. Description of the Related Art

An imprinting method is known as a method of forming a microscopic pattern on a substrate so as to manufacture a semiconductor device or the like. In the imprinting method, imprint material (such as light-curable resin) is cast into a pattern that is formed on a substrate by using a mold having a relief pattern. If the substrate carrying the pattern is further processed in a state where a residual layer formed at the bottom of the pattern has significantly nonuniform thickness (in a state where the nonuniformity in the thickness of the residual layer is significant), a resulting article may fail to exhibit desired performance.

U.S. Patent Laid-Open No. 2007/0228593 has disclosed a method of reducing the nonuniformity in the thickness of the residual layer. Specifically, new data on the distribution of imprint material to be applied onto the substrate is created in accordance with the nonuniformity in the thickness of the residual layer that has been acquired by measuring the residual layer in a plurality of areas of the pattern formed of the imprint material. For example, a method of creating data on material distribution has been disclosed in which a larger amount of imprint material is applied to areas where the residual layer is expected to be thinner than in other areas.

### SUMMARY OF THE INVENTION

The present inventors have found that the uniformity in the thickness of the residual layer is affected by the state of the imprint material that changes while the substrate carrying uncured imprint material moves along a horizontal plane. This aspect is not referred to in U.S. Patent Laid-Open No. 2007/0228593.

The present invention provides an imprinting apparatus, a method of creating data on material distribution, and an imprinting method in each of which data on a distribution of imprint material that reduces nonuniformity in the thickness of a residual layer is created.

According to an aspect of the present invention, there is provided an imprinting apparatus that forms patterns sequentially on a plurality of areas of a substrate by using a mold and imprint material. The apparatus includes a moving unit configured to be movable along a horizontal plane while carrying the substrate on which the imprint material is provided, and an applying unit configured to apply the imprint material onto the substrate based on information related to a state of the imprint material and information related to an order of pattern formation, the information related to the state of the imprint material varying with the movement of the moving unit.

Further features of the present invention will become apparent from the following description of exemplary embodiments with reference to the attached drawings.

### BRIEF DESCRIPTION OF THE DRAWINGS

FIG. 1 illustrates an imprinting apparatus according to a first embodiment of the present invention.

FIG. 2 illustrates a dispenser.

FIGS. 3A and 3B each illustrate an order of imprinting.

FIG. 4 is a graph illustrating positional deviation of a substrate stage from an instructed position.

FIGS. 5A to 5F illustrate a relationship between the direction of movement of the substrate stage and the inclination of the substrate stage.

FIGS. 6A to 6D each illustrate a residual layer formed after imprinting.

FIG. 7 is a flow chart illustrating a method of creating a droplet pattern.

FIGS. 8A to 8C illustrate exemplary droplet patterns.

FIG. 9 is a flow chart illustrating an imprinting process.

FIGS. 10A to 10E illustrate steps of the imprinting process.

FIG. 11 illustrates a relationship between the order of imprinting and the thickness of the residual layer.

FIGS. 12A and 12B each illustrate a state of pattern formation.

FIG. 13 illustrates a droplet pattern according to a third embodiment of the present invention.

### DESCRIPTION OF THE EMBODIMENTS

### First Embodiment

### Configuration of Apparatus

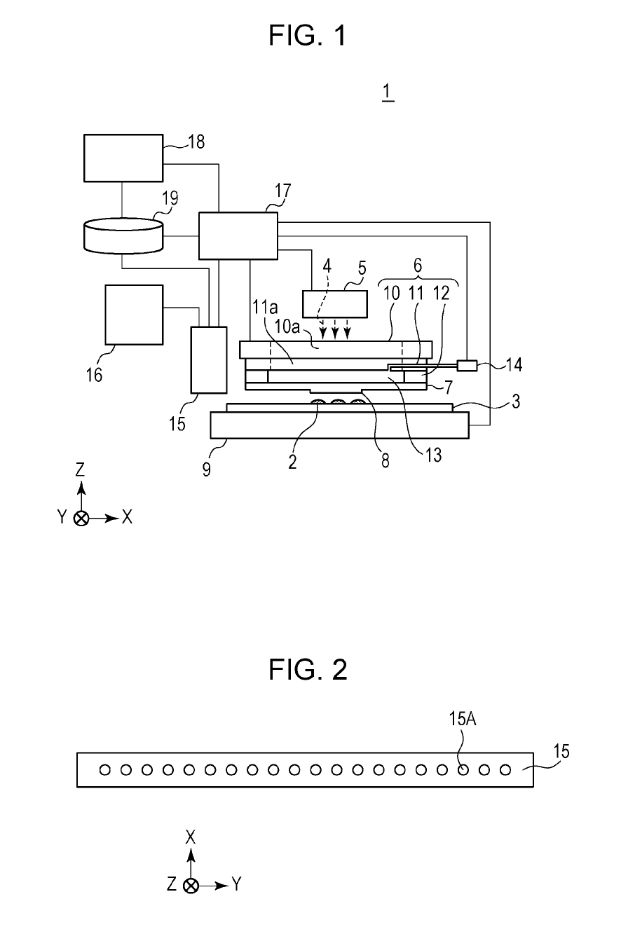

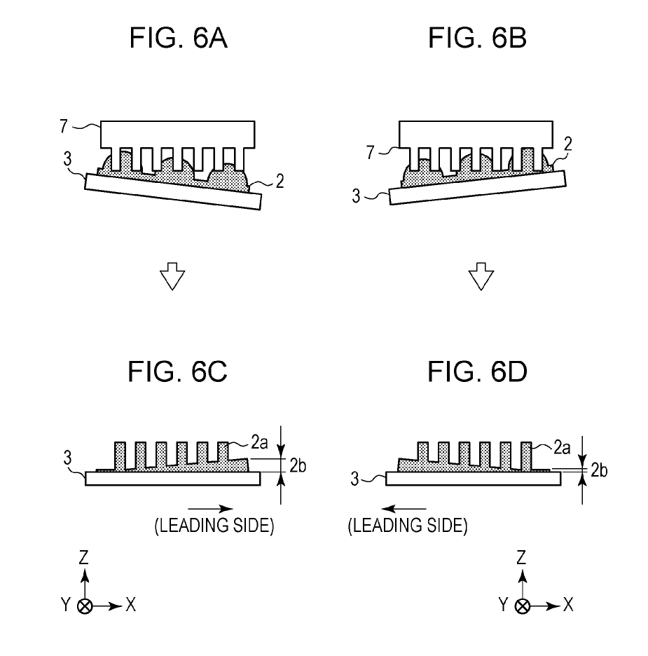

FIG. 1 illustrates an imprinting apparatus 1 according to a first embodiment of the present invention. Referring to FIG. 1, a substrate stage 9 carries a substrate 3 such as a wafer and moves along a horizontal plane. The term “horizontal plane” refers to a plane that is perpendicular to the direction of gravitational force. The phrase “to move along the horizontal plane” encompasses a case where the substrate stage 9 moves while inclining with respect to the horizontal plane by a small angle within a range of control error that may occur when the substrate stage 9 is driven. In the first embodiment, a term “information related to the state of imprint material” refers to likely nonuniformity in the thickness of a residual layer 2b (see FIGS. 6A to 6D) included in a pattern formed of imprint material that are estimated from the direction of movement of the substrate stage 9 (the information is hereinafter referred to as “likely residual-layer information”). The likely residual-layer information will be described later.

The imprinting apparatus 1 forms a relief pattern of ultraviolet-curable resin (imprint material) 2 by using a mold 7 and ultraviolet light 4. A light source 5 is a device such as a halogen lamp or a light-emitting diode (LED) and emits the ultraviolet light 4 toward the substrate 3. The light source 5 is provided vertically above (on the +Z side of) a mold stage 6 and applies the ultraviolet light 4 to the imprint material 2 on the substrate 3 through the mold 7.

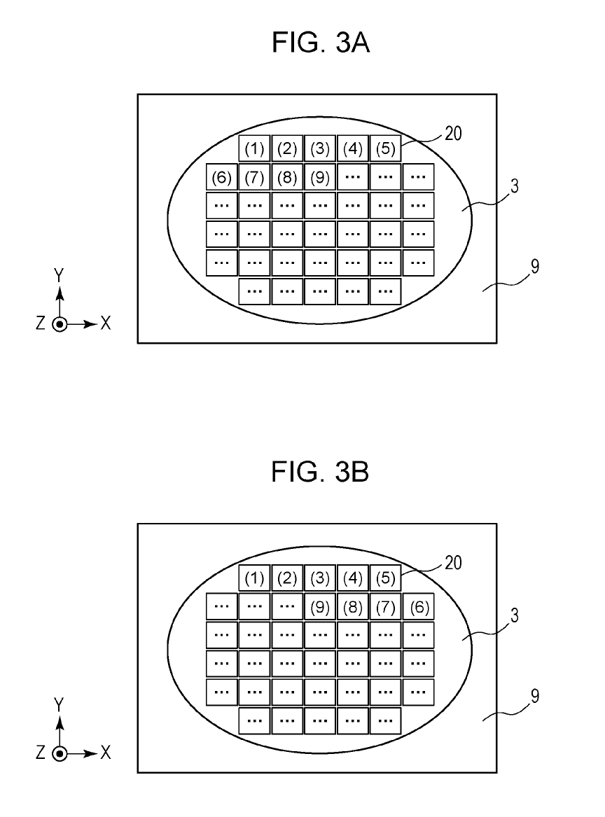

The mold stage 6 that holds the mold 7 on a side (−Z side) thereof facing the substrate 3 positions the mold 7 while holding the mold 7. The mold 7 has a relief pattern in a central part 8. While the first embodiment concerns a case where the mold 7 has a relief pattern covering one shot area 20 (see FIGS. 3A and 3B), the mold 7 may have a relief pattern covering a plurality of shot areas 20.

The substrate stage (moving unit) 9 that is movable while carrying the substrate 3 having the imprint material 2 applied (supplied) thereto is capable of positioning the substrate 3 in three axial directions including the direction in which the horizontal plane extends.

The mold stage 6 includes a coarse-adjustment stage 10 that coarsely adjusts the position of the mold 7, a fine-adjustment stage 11 that finely adjusts the position of the mold 7 by units of a smaller length than the coarse-adjustment stage 10 does, and a holding portion 12 that holds the mold 7, which are stacked in that order from the top. The mold 7 can be positioned in six axial directions by the coarse-adjustment stage 10 and the fine-adjustment stage 11.

The coarse-adjustment stage 10 has an opening 10a in a central part thereof. The fine-adjustment stage 11 has an opening 11a in a central part thereof. The mold 7 is made of a material (such as quartz) that transmits the ultraviolet light 4. Hence, the ultraviolet light 4 emitted from the light source 5 is transmitted through the mold 7 and falls onto the imprint material 2 on the substrate 3. Note that a plate member (not illustrated) that transmits the ultraviolet light 4 is provided between the fine-adjustment stage 11 and the holding portion 12.

The holding portion 12 is capable of holding the mold 7 by the use of a vacuum suction force or an electrostatic force. The holding portion 12 has an opening in a central part thereof in such a manner as to hold only a peripheral part of the relief pattern. The opening is provided between the mold 7 and the plate member, whereby a space 13 is provided.

A pressure-adjusting unit 14 communicates with the space 13. The pressure-adjusting unit 14 includes a vacuum pump (not illustrated) and adjusts the pressure in the space 13. To form a pattern on the substrate 3, the shape of the mold 7 is changeable such that relevant parts of the mold 7 project or are depressed in the vertical direction.

In the following description, to bring the imprint material 2 on the substrate 3 and the mold 7 into contact with each other and fill the mold 7 having the relief pattern with the imprint material 2 (this process is hereinafter referred to as “imprinting”), the mold stage 6 is moved in the Z-axis direction. Alternatively, as long as imprinting is performable, at least one of the mold stage 6 and the substrate stage 9 may be moved in the Z-axis direction.

A dispenser (applying unit) 15 applies the imprint material 2 to a predetermined position of the substrate 3 while receiving the supply of imprint material 2 from a tank 16 that stores uncured imprint material 2. FIG. 2 is a bottom view of the dispenser 15. The dispenser 15 has a line of ejection ports 15A from which the imprint material 2 is ejected.

Each of the ejection ports 15A ejects the imprint material 2 toward the substrate 3 by units of a predetermined amount (the unit is hereinafter defined as “drop”). The amount of ejection per drop ranges from subpicoliters to several picoliters. The dispenser 15 applies the imprint material 2 onto the substrate 3 along lines that are at intervals of several micrometers to dozens of micrometers. The dispenser 15 ejects an amount of imprint material 2 that is necessary for a single imprinting action on a single shot area 20 while the substrate 3 is moving below the dispenser 15. Thus, uncured imprint material 2 (hereinafter simply referred to as “imprint material 2”) is applied to a single shot area 20.

The dispenser 15 applies the imprint material 2 to an area on the substrate 3 in accordance with an imprint-material-droplet pattern (data on the distribution of imprint material 2) created by a creating unit 18 to be described later. The droplet pattern is also referred to as an application map or a drop recipe. The droplet pattern is data representing the droplet layout and the amount of imprint material 2 necessary in a single imprinting action (also referred to as “data on material distribution”). The data on material distribution is adjustable by increasing or decreasing at least one of the amount of imprint material 2 to be ejected and the number of positions of application of the imprint material 2 in a single imprinting action.

Referring now to FIG. 1, a control unit 17 includes a central processing unit (CPU), a random access memory (RAM), a hard disk drive (HDD), and so forth. The control unit 17 generally controls a series of operations of the imprinting apparatus 1 (hereinafter referred to as “imprinting process”) that are performed for forming a relief pattern made of the imprint material 2. For example, the control unit 17 notifies the target position of the mold stage 6 and the target position of the substrate stage 9, instructs the light source 5 to emit the ultraviolet light 4 toward the substrate 3 at a predetermined timing, reads a desired droplet pattern from a storage unit 19 storing different imprint-material-droplet patterns, transmits the droplet pattern to the dispenser 15, and notifies the pressure-adjusting unit 14 of a target pressure to be generated during the imprinting process.

The storage unit 19 stores relief patterns prepared for the mold 7, mold information related to the mold 7 of interest, and droplet patterns created by the below-described creating unit 18. The storage unit 19 further stores dispenser information, imprinting-atmosphere information, information related to the direction of movement of the substrate stage 9, information related to the order of imprinting in accordance with which imprinting is performed sequentially on a plurality of shot areas 20 of the substrate 3 (information related to the order of pattern formation; see FIG. 3), and so forth.

The mold information is a set of pieces of information related to the mold 7 of interest and includes, for example, the line width, the density, and any defects of the relief pattern of the mold 7, the number of times of performance of the imprinting process using a specific mold 7, the number of times of performance of a cleansing process regarding a specific mold 7, and so forth. The dispenser information is a set of pieces of information related to the dispenser 15 and includes, for example, the number of ejection ports 15A of the dispenser 15, the average amount of imprint material 2 ejected per ejection port 15A, the actual amounts of imprint material 2 ejected from the respective ejection ports 15A, the actual positions to which the imprint material 2 is ejected from the respective ejection ports 15A, and so forth. The imprinting-atmosphere information is a set of pieces of information related to the imprinting process and includes, for example, the ambient temperature, the air current, and the oxygen concentration around the location where imprinting is performed, the kind of the imprint material 2, the volatility of the imprint material 2, and so forth.

The information related to the direction of movement of the substrate stage 9 represents the direction in which the substrate 3 to which the imprint material 2 has been applied moves from a position facing the dispenser 15 to a position facing the mold 7 (hereinafter referred to as “imprinting position”) where imprinting is to be performed. The storage unit 19 according to the first embodiment stores the likely residual-layer information that correlates with the information related to the direction of movement of the substrate stage 9.

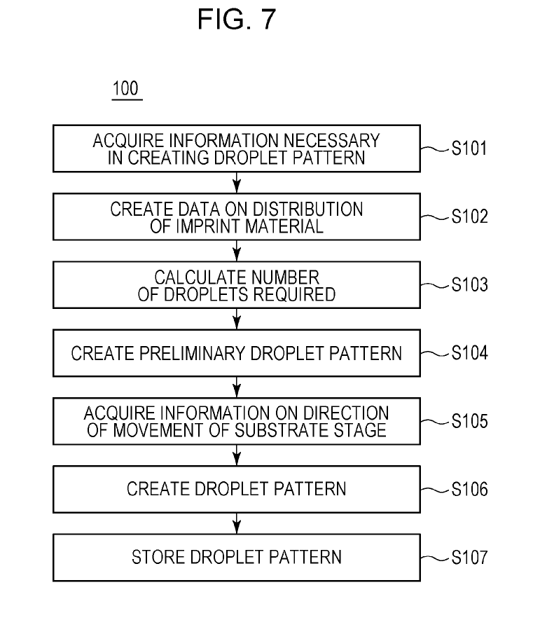

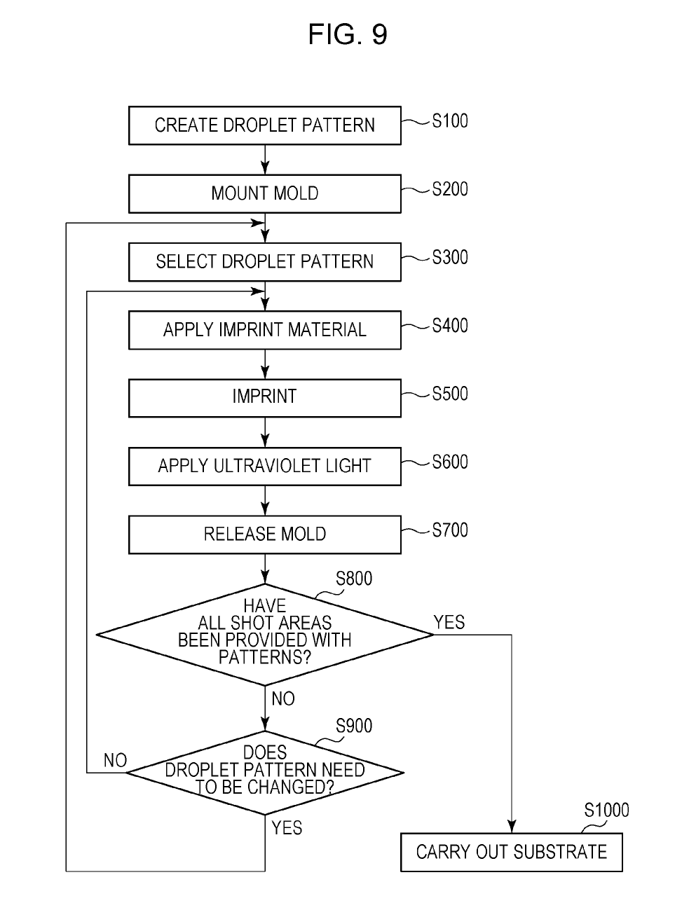

The storage unit 19 stores a program for creating a droplet pattern, which is summarized as a flow chart in FIG. 7, and a program for performing the imprinting process on all of the shot areas 20 of the substrate 3, which is summarized as a flow chart in FIG. 9.

The creating unit 18 that creates a droplet pattern includes a CPU. When the creating unit 18 runs the program summarized in FIG. 7, a droplet pattern is created. The creating unit 18 creates a droplet pattern on the basis of the mold information, the dispenser information, and the likely residual-layer information.

Now, how the substrate stage 9 moves will be described with reference to FIGS. 3A, 3B, 4, 5A to 5F, and 6A to 6D. FIGS. 3A and 3B each illustrate an order of imprinting. The imprinting apparatus 1 forms patterns sequentially on a plurality of shot areas (a plurality of areas) 20, which are objects of pattern formation, respectively. The numbers in parentheses given in the respective shot areas 20 represent the order of imprinting. Specifically, in the case illustrated in FIG. 3A, patterns start to be formed on shot areas 20 in the first row sequentially in the +X direction, and then on shot areas 20 in the second row sequentially in the +X direction.

In the case illustrated in FIG. 3B, patterns start to be formed on shot areas 20 in the first row sequentially in the +X direction, and then on shot areas 20 in the second row sequentially in the −X direction. After the completion of every imprinting action of forming a pattern on a single shot area 20, the substrate stage 9 moves from the imprinting position to the position facing the dispenser 15.

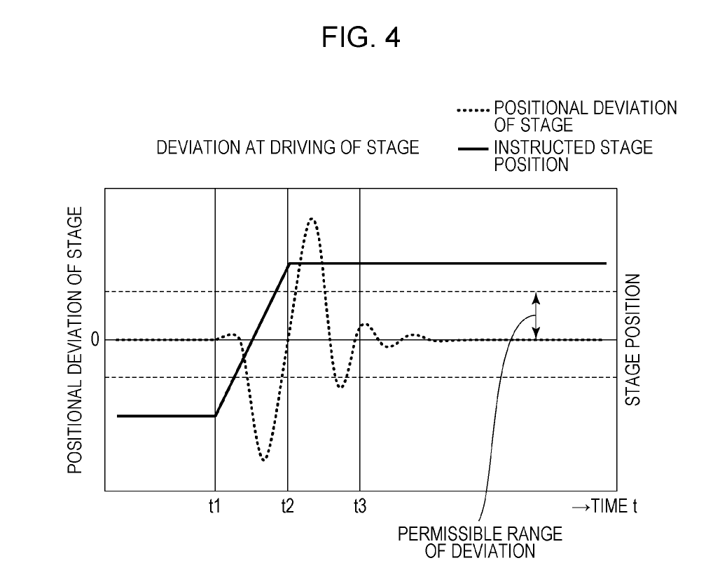

A relationship between the direction of movement of the substrate stage 9 and the likely residual-layer information will now be described. The substrate stage 9 is positioned with a delay in response to a control command (a command that indicates the target position with respect to time) issued thereto. In the graph illustrated in FIG. 4, the horizontal axis represents time, and the vertical axis represents the position of the substrate stage 9 for the solid line and the positional deviation of the substrate stage 9 from the instructed position (the positional error of the substrate stage 9 with respect to the instructed position) for the dotted line. For example, the graph shows that, even if the substrate stage 9 is instructed to start to move at time t1 and to stop at time t2, the substrate stage 9 is not stabilized at time t2 but the positional deviation of the substrate stage 9 falls into a permissible range of deviation at time t3.

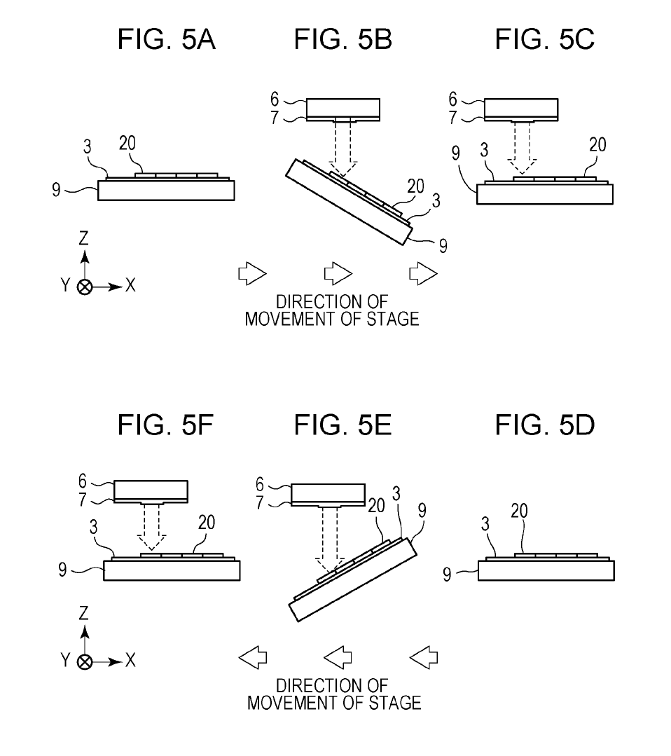

FIGS. 5A to 5F illustrate the direction of movement of the substrate stage 9 and the inclination of the substrate stage 9. FIGS. 5A and 5D each illustrate a state of the substrate stage 9 during a period from time t1 to time t2. FIGS. 5B and 5E each illustrate a state of the substrate stage 9 during a period from time t2 to time t3. FIGS. 5C and 5F each illustrate a state of the substrate stage 9 after time t3. As illustrated in FIGS. 5B and 5E, the substrate stage 9 moving in the +X direction tends to incline slightly such that the +X side thereof is positioned lower than the other side thereof, and the substrate stage 9 moving in the −X direction tends to incline slightly such that the −X side thereof is positioned lower than the other side thereof.

In the first embodiment, the control unit 17 puts the priority on the throughput and controls the mold stage 6 such that imprinting is performed during the period from time t2 to time t3. In such a case, if the creating unit 18 does not create any droplet pattern by using the below-described method, the imprint material 2 and the mold 7 are brought into contact with each other while the substrate 3 is inclined downward on the leading side (see FIG. 6A or 6B). Consequently, a residual layer 2b whose thickness is significantly nonuniform is formed at the bottom of patterned imprint material 2a (hereinafter referred to as “imprint-material pattern 2a”; see FIG. 6C or 6D). The residual layer 2b refers to a layer of imprint material 2 that is formed at the bottom (in the valleys) of the imprint-material pattern 2a in the imprinting process.

The information related to the direction of movement of the substrate stage 9 that is used in the first embodiment is the direction in which the substrate stage 9 moves from the position facing the dispenser 15 to the position where imprinting is performed. That is, in the case of the imprinting apparatus 1, the direction of movement of the substrate stage 9 is the +X direction. The likely residual-layer information according to the first embodiment is the information indicating that the residual layer 2b is likely to be thicker on the leading side (+X side) than on the trailing side (−X side) that is opposite the leading side in a single shot area 20 (see FIGS. 5A to 5F and 6A to 6D). The trailing side is opposite the leading side.

### (Method of Creating Droplet Pattern)

A method 100 of creating a droplet pattern according to the first embodiment will now be described with reference to FIG. 7. The method 100 is performed for reducing the variation in the thickness of the residual layer 2b, i.e., the nonuniformity in the thickness of the residual layer 2b. That is, a droplet pattern with which the nonuniformity in the thickness of the residual layer 2b included in the resulting pattern that may occur in accordance with the direction of movement of the substrate stage 9 is reduced is created.

FIG. 7 is a flow chart illustrating the method 100 of creating a droplet pattern. In step S101, the creating unit 18 acquires pieces of information necessary in creating a droplet pattern: namely, the mold information, the dispenser information, the imprinting-atmosphere information, and so forth. In step S102, the creating unit 18 creates data on the distribution of imprint material 2, which is an estimation of the required amount of imprint material 2 for each of sections of a single shot area 20, on the basis of the pieces of information acquired in step S101.

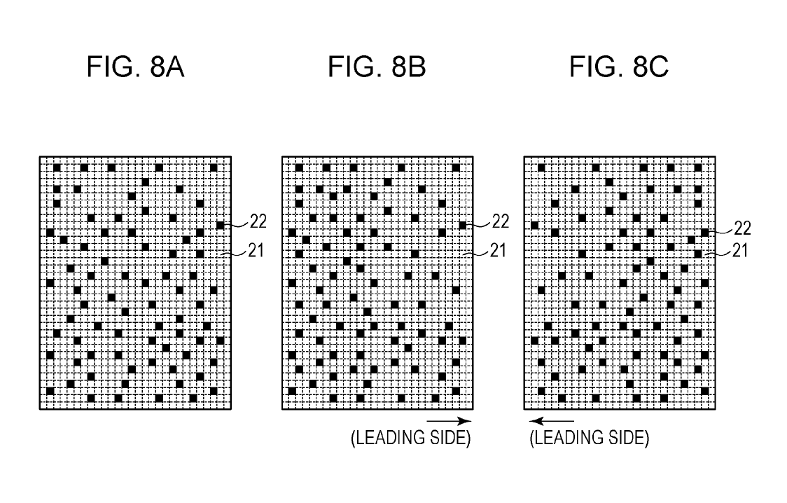

In step S103, the creating unit 18 calculates the number of droplets of imprint material 2 that is required for a single imprinting action from information indicating the size of each droplet ejected from the dispenser 15. In step S104, the calculated number of droplets are roughly allocated among the sections of the shot area 20, whereby a preliminary droplet pattern is created. An example of the preliminary droplet pattern is illustrated in FIG. 8A. The area illustrated in FIG. 8A corresponds to a single shot area 20. Blank rectangular sections 21 correspond to sections where no imprint material 2 is to be applied. Black rectangular sections 22 correspond to sections where the imprint material 2 is to be applied.

Referring to FIG. 7, in step S105, the creating unit 18 acquires the information related to the direction of movement of the substrate stage 9 and the likely residual-layer information corresponding to the information related to the direction of movement of the substrate stage 9 from the storage unit 19. In step S106, the creating unit 18 creates a droplet pattern to be set on the dispenser 15 from the likely residual-layer information and the preliminary droplet pattern that have been acquired in steps S104 and S105. The droplet pattern created in step S106 is composed of the same number of droplets of imprint material 2 as the preliminary droplet pattern, but the droplets are distributed in a different way. In step S107, the creating unit 18 stores the droplet pattern that have been acquired in step S106 to the storage unit 19.

For example, the creating unit 18 creates a droplet pattern illustrated in FIG. 8B. In this droplet pattern, the density of the imprint material 2 to be applied (hereinafter also referred to as “application density”) on the leading side (a side nearer to the destination) on which the residual layer 2b tends to be thick is made lower than the density of the imprint material 2 to be applied on the trailing side (a side farther from the destination) on which the residual layer 2b tends to be thin. If the imprint material 2 is applied on the basis of the droplet pattern created in step S106, the nonuniformity in the thickness of the residual layer 2b included in the resulting pattern is reduced. The term “application density” refers to the amount of imprint material 2 per unit area. The application density is adjustable by increasing or decreasing at least one of the amount of imprint material 2 to be ejected from the dispenser 15 in a single ejecting action (the amount of imprint material 2 per droplet) and the number of points to which the imprint material 2 is to be applied.

If the dispenser 15 is on the +X side with respect to the mold 7 and the substrate 3 having the imprint material 2 moves in the −X direction toward the imprinting position, another droplet pattern is created. FIG. 8C illustrates an exemplary droplet pattern created in the case where the substrate stage 9 moves in the −X direction. In the case where the substrate stage 9 moves in the −X direction also, a droplet pattern is created such that the density of the imprint material 2 to be applied on the leading side on which the residual layer 2b tends to be thick becomes lower than the density of the imprint material 2 to be applied on the trailing side on which the residual layer 2b tends to be thin.

The creating unit 18 creates a plurality of droplet patterns for one kind of mold information. The reason for this is as follows. Occasionally, in the imprinting process, part of the relief pattern of the mold 7 may protrude from the substrate 3. Therefore, a droplet pattern with which the imprint material 2 is prevented from being ejected toward such protruding part of the relief pattern also needs to be created.

### (Flow of Imprinting Process)

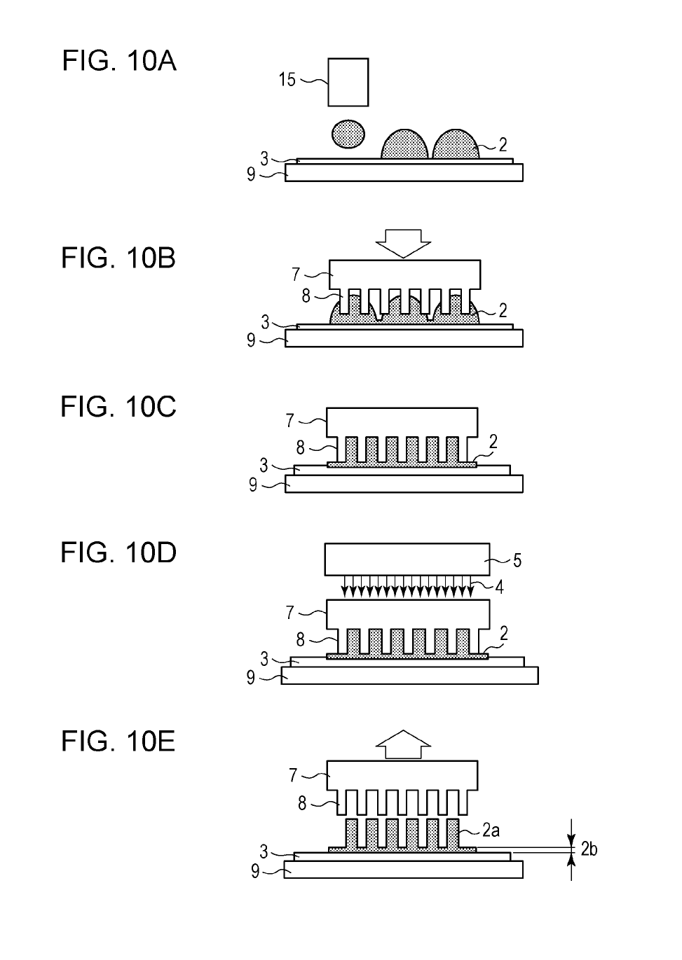

A flow of the imprinting process will now be described with reference to FIGS. 9 and 10A to 10E. FIG. 9 is a flow chart illustrating a program of the imprinting process. FIGS. 10A to 10E illustrate steps of the imprinting process. When the control unit 17 runs the program illustrated in FIG. 9, the imprinting process is performed.

First, in step S100, the creating unit 18 creates a droplet pattern in accordance with the method 100 described above. In step S200, a conveying mechanism (not illustrated) mounts the mold 7 having a desired relief pattern onto the mold stage 6.

In step S300, the control unit 17 acquires the mold information related to the mold 7 of interest and acquires a set of droplet patterns corresponding to that mold 7. The control unit 17 selects a shot area 20 on which a pattern is to be formed, and sets one of the droplet patterns that corresponds to the direction of movement of the substrate stage 9 in that shot area 20 on the dispenser 15.

In step S400, the dispenser 15 applies uncured imprint material 2 onto the substrate 3 in accordance with the droplet pattern that has been set as above (see FIG. 10A). In step S500, when the substrate 3 has moved from the position facing the dispenser 15 to the imprinting position, the mold 7 is pressed into the imprint material 2 at a predetermined timing (see FIG. 10B). The predetermined timing refers to a point of time (between time t2 and time t3) before the positional deviation of the substrate stage 9 falls into the permissible range.

In step S600, after the recesses of the mold 7 are filled with the imprint material 2 (see FIG. 10C), the light source 5 emits the ultraviolet light 4 for over a predetermined period of time, whereby the imprint material 2, which has not been cured, is cured (see FIG. 10D). In step S700, the mold stage 6 removes the mold 7 (see FIG. 10E). Thus, an imprint-material pattern 2a is formed on the substrate 3.

The droplet pattern created by the creating unit 18 is based on the likely residual-layer information. Since the dispenser 15 applies the imprint material 2 in accordance with the droplet pattern created for reducing the nonuniformity in the thickness of the residual layer 2b, the thickness of the residual layer 2b of the imprint-material pattern 2a becomes substantially uniform. In step S800, the control unit 17 checks if all of the shot areas 20 of the substrate 3 have been provided with respective patterns. If so (YES), the process proceeds to step S1000, in which the control unit 17 allows the substrate 3 to be carried out.

If there are any shot areas 20 provided with no patterns (NO), the process proceeds to step S900, in which the control unit 17 selects one of such shot areas 20 and checks if the droplet pattern needs to be changed in performing imprinting on that shot area 20.

The droplet pattern needs to be changed if, for example, the direction of movement of the substrate stage 9 in a shot area 20 that is to be subjected to imprinting next is different from the direction of movement of the substrate stage 9 in another shot area 20 that has been subjected to imprinting last time or if part of the relief pattern of the mold 7 protrudes from the substrate 3 during the imprinting process. If the droplet pattern needs to be changed, the process returns to step S300, in which another appropriate droplet pattern is selected. Then, steps S400 to S900 are performed again. If the droplet pattern does not need to be changed, steps S400 to S900 are performed with the same droplet pattern. Regarding the next substrate 3 and substrates 3 included in the next lot also, patterns are formed on the basis of appropriate droplet patterns selected by the control unit 17.

The droplet pattern may be reselected after patterns are formed on a predetermined number of shot areas 20 or after a single substrate 3 is processed, by acquiring information related to any defective-pattern inspection or any information related to irregular-pattern detection from the inside or the outside of the imprinting apparatus 1. Alternatively, a brand new droplet pattern may be created. The defective-pattern information refers to the result of any measurement of the accuracy in the transfer of the pattern made of the imprint material 2 and is acquired by an inspection device (not illustrated). The information related to irregular-pattern detection includes pieces of information indicating any irregularity in the accuracy of arrangement of droplets ejected by the dispenser 15, any irregularity in the force of pressing or releasing the mold 7, the presence of any impurities taken in during the imprinting process, the exceeding of a predetermined number of times of use of the mold 7, and so forth.

As described above, in the first embodiment, the creating unit 18 creates a droplet pattern on the basis of the information related to the direction of horizontal movement of the substrate stage 9 and the likely residual-layer information that correlates with the information related to the direction of movement of the substrate stage 9. Then, the dispenser 15 applies the imprint material 2 in accordance with the droplet pattern created by the creating unit 18. Even if the priority is put on the throughput and imprinting is performed before the substrate 3 is stabilized, the nonuniformity in the thickness of the residual layer 2b of the imprint-material pattern 2a can be made lower (the uniformity in the thickness of the residual layer 2b can be made higher) than in a case where the first embodiment is not applied.

The likely residual-layer information is stored in advance in the storage unit 19. Therefore, even if the substrate stage 9 moves in a new direction to the imprinting position, the creating unit 18 can create a droplet pattern that reduces the nonuniformity in the thickness of the residual layer 2b without the performance of the measurement of the thickness of the residual layer 2b. Hence, at least a period of time that may be consumed for the first measurement of the thickness of the residual layer 2b at the beginning of the imprinting process can be saved.

If the substrate 3 having the imprint material 2 and moving away from the position facing the dispenser 15 moves to the imprinting position without taking the shortest route, the information related to the direction of movement of the substrate stage 9 may indicate a direction in which the substrate stage 9 moves from a position of the last stop to the imprinting position.

### Second Embodiment

The inclination of the substrate stage 9 at the imprinting position varies with the speed of the substrate stage 9. In a second embodiment of the present invention, the creating unit 18 creates droplet patterns with different levels of nonuniformity in the application density on the basis of the direction of movement of the substrate stage 9, the likely residual-layer information estimated from the direction of movement of the substrate stage 9, and information related to the speed at which the substrate stage 9 moves along the horizontal plane.

The information related to the speed of the substrate stage 9 is information indicating the level of the speed or the rate of acceleration or the like of the substrate stage 9. Creating droplet patterns on the basis of such information related to the speed of the substrate stage 9 provides a residual layer 2b having substantially uniform thickness, even if the inclination of the substrate stage 9 at the imprinting position varies with the speed of the substrate stage 9.

In step S105 of the flow chart illustrated in FIG. 7 described in the first embodiment, the creating unit 18 according to the second embodiment acquires the information related to the speed of the substrate stage 9 as well, and creates a droplet pattern on the basis of those pieces of information. For example, in a droplet pattern created for the substrate stage 9 moving fast, the application density varies wider among areas of the substrate 3 than in a droplet pattern created for the substrate stage 9 moving more slowly.

### Third Embodiment

Information related to the state of the imprint material 2 according to a third embodiment of the present invention corresponds to the likely residual-layer information or may indicate the state of the imprint material 2 that correlates with the likely residual-layer information and that is observed while the substrate stage 9 is moving. For example, the information related to the state of the imprint material 2 indicates the way the volume of each of the droplets applied to the substrate 3 changes because of volatilization.

Information related to the order of pattern formation according to the third embodiment corresponds to the order of imprinting: that is, as illustrated in FIGS. 3A and 3B, information indicating in what ordinal number each of the shot areas 20 undergoes pattern formation. The information related to the order of pattern formation may indicate the order of imprinting in a case where patterns are formed on a plurality of shot areas 23 in a single imprinting action.

In the imprinting apparatus 1 according to the third embodiment, the creating unit 18 creates droplet a pattern on the basis of the order of imprinting and the likely residual-layer information. Even if the direction of movement of the substrate stage 9 from the position facing the dispenser 15 to the imprinting position is constant, the state of the residual layer 2b may be affected by factors such as the air current in the imprinting apparatus 1 or the air current occurring with the movement of the substrate stage 9. The third embodiment is advantageous in a case where the state of the residual layer 2b is not constant because of the difference in the order of imprinting.

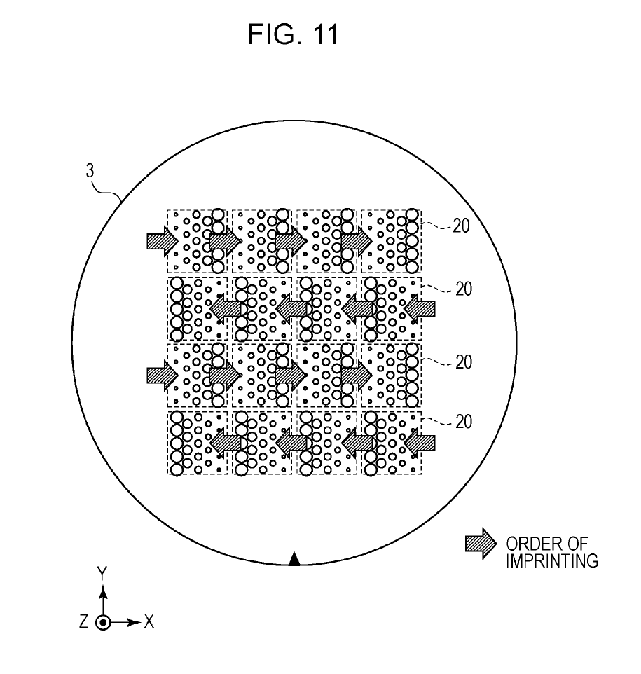

FIG. 11 illustrates a relationship between the order of imprinting and the likely residual-layer information in a case where the imprint-material pattern 2a is formed in the order of imprinting that is illustrated in FIG. 3B. The size of circles drawn in each of a plurality of shot areas 20 corresponds to the thickness of the residual layer 2b. Specifically, the larger the circle, the thicker the residual layer 2b.

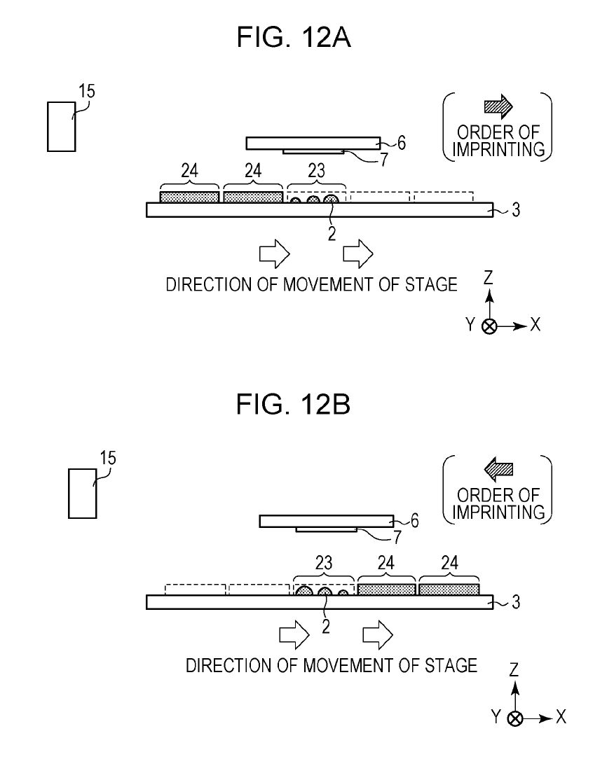

FIGS. 12A and 12B each illustrate a relationship between the order of imprinting and the state of pattern formation. A shot area 23 (a first area) has the imprint material 2 but is yet to undergo pattern formation. On the other hand, shot areas 24 (second areas) each have an imprint-material pattern 2a. In FIGS. 12A and 12B, the states of the droplets of imprint material 2 on the shot area 23 have changed because of volatilization that has occurred while the substrate stage 9 has been moving.

Referring to FIG. 11, in the first row, patterns are formed sequentially toward the leading side (+X side) of the substrate stage 9. That is, as illustrated in FIG. 12A, the substrate stage 9 moves with the shot area 23 being on the leading side of the substrate stage 9 with respect to the shot areas 24. In this case, the likely residual-layer information indicates that the residual layer 2b tends to be thicker on the leading side of the substrate stage 9 than on the trailing side opposite the leading side.

Referring to FIG. 11, in the second row, patterns are formed sequentially toward the trailing side (the −X side) opposite the leading side. That is, as illustrated in FIG. 12B, the substrate stage 9 moves with the shot areas 24 being on the leading side of the substrate stage 9 with respect to the shot area 23. In this case, the likely residual-layer information indicates that the residual layer 2b tends to be thinner on the leading side of the substrate stage 9 than on the trailing side opposite the leading side.

Now, the imprinting apparatus 1 according to the third embodiment will be described. The storage unit 19 according to the third embodiment stores the order of imprinting, and the likely residual-layer information that correlates with the order of imprinting. The likely residual-layer information according to the third embodiment indicates the tendency of the nonuniformity in the thickness of the residual layer 2b that is estimated from the order of imprinting and the direction of movement of the substrate stage 9. In the third embodiment, imprinting is performed in a state where the substrate stage 9 has been stabilized with the positional deviation thereof being within the permissible range. The imprinting process performed in the third embodiment is the same as that described in the first embodiment, except the method of creating a droplet pattern by the creating unit 18. Therefore, redundant description is omitted.

The creating unit 18 creates a droplet pattern in accordance with the order of imprinting (information that correlates with the state of the imprint material 2 and that varies with the movement of the moving unit) and the likely residual-layer information that correlates with the order of imprinting.

A case where patterns are formed sequentially toward the leading side of the substrate stage 9 as in the case of the first row illustrated in FIG. 11 will now be described. The creating unit 18 creates a droplet pattern with which the imprint material 2 can be applied to the shot area 23 such that the density of the imprint material 2 becomes lower on the leading side on which the residual layer 2b tends to be thick than on the trailing side on which the residual layer 2b tends to be thin (see FIG. 8B). In other words, the creating unit 18 creates a droplet pattern (second data) such that, in the state where the shot area 23 is on the trailing side of the substrate stage 9 with respect to the shot areas 24, the density of the imprint material 2 applied on the leading side becomes lower than the density of the imprint material 2 applied on the trailing side.

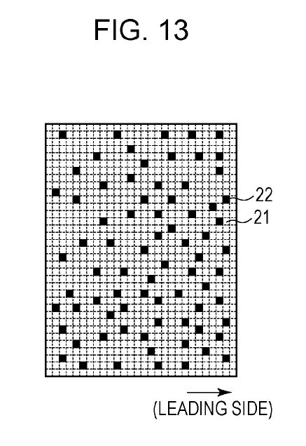

A case where patterns are formed sequentially toward the trailing side of the substrate stage 9 as in the case of the second row illustrated in FIG. 11 will now be described. The creating unit 18 creates a droplet pattern (first data; see FIG. 13) with which the imprint material 2 can be applied to the shot area 23 such that the density of the imprint material 2 becomes higher on the leading side on which the residual layer 2b tends to be thin than on the trailing side on which the residual layer 2b tends to be thick. In other words, the creating unit 18 creates a droplet pattern such that, in the state where the shot area 23 is on the leading side of the substrate stage 9 with respect to the shot areas 24, the density of the imprint material 2 applied on the leading side becomes higher than the density of the imprint material 2 applied on the trailing side.

Since the creating unit 18 creates a droplet pattern on the basis of the order of imprinting and the likely residual-layer information, a droplet pattern that reduces the nonuniformity in the thickness of the residual layer 2b can be created even if the likely state of the residual layer 2b varies with the order of imprinting.

The information related to the order of pattern formation only needs to be information that clarifies the positional relationship between the shot area 23 and the shot areas 24. That is, any information other than the information related to the order of imprinting may also be taken.

For example, comparing the position of a shot area 20 on which a pattern has been formed in an n-th order and the position of a shot area 20 on which a pattern is to be formed in an n+1-th order, information indicating whether or not the direction from the shot area 20 on which the pattern has been formed in the n-th order toward the shot area 20 on which the pattern is to be formed in the n+1-th order is the same as the direction of movement of the substrate stage 9 (information related to the positional relationship between patterns that are formed successively) may be taken. Alternatively, information indicating whether or not the shot areas 24 are present on the leading side of the substrate stage 9 (information indicating the presence of the second area on the leading side with respect to the first area) may be taken. Alternatively, information indicating where in the XY plane the shot areas 24 are present (information related to the position of the second area) may be taken.

Alternatively, the creating unit 18 may create a droplet pattern on the basis of the position of a member (not illustrated) that supplies inert gas to an area around the imprinting position so as to push away the ambient air. Alternatively, the creating unit 18 may create a droplet pattern on the basis of the distance and the direction of movement of the substrate stage 9 up to the imprinting position. As in the second embodiment, the creating unit 18 may create a droplet pattern on the basis of information related to the speed of the substrate stage 9. The order of imprinting is not limited to those illustrated in FIGS. 3A and 3B. Imprinting may be performed in a random order, a zigzag order, or the like.

### Other Embodiments

Other embodiments of the present invention will now be described.

The imprinting apparatus 1 may include a plurality of dispensers 15. In that case, the direction from the position facing any of the dispensers 15 that has ejected the imprint material 2 to a shot area 20 of interest toward the imprinting position is regarded as the direction of movement of the substrate stage 9. The creating unit 18 creates a suitable droplet pattern on the basis of the likely residual-layer information related to the imprint-material pattern 2a that is acquired from information related to different movements of the substrate stage 9 that are based on the different dispensers 15.

Since different dispensers 15 are used in accordance with the position of the shot area 23 of the substrate 3, the number of pieces of likely residual-layer information increases. Even in such a case, both the nonuniformity in the thickness of the residual layer 2b in a single shot area 20 and the nonuniformity in the thickness of the residual layer 2b among a plurality of shot areas 20 can be reduced.

The direction of movement of the substrate stage 9 is identified by the position of the shot area 20 of interest on the substrate 3, the position of the dispenser 15, and the imprinting position. The direction of movement of the substrate stage 9 may be identified by the creating unit 18 from the foregoing pieces of information, or may be calculated by the control unit 17 and be stored in the storage unit 19 so as to be used later.

The creating unit 18 may be provided on the outside of the imprinting apparatus 1. The data on the droplet pattern that is created by the creating unit 18 may be supplied to the storage unit 19 through an information-storage medium or over wired or wireless communications. The control unit 17, the storage unit 19, and the creating unit 18 may be all provided on a single control board or on separate control boards, as long as the units 17, 18, and 19 have the respective functions described above.

To reduce the nonuniformity in the thickness of the residual layer 2b, the method of creating a droplet pattern according to each of the first to third embodiments may be combined with a method of adjusting the inclination of the mold 7. In that case, when the inclination of the mold 7 is changed, the creating unit 18 changes the nonuniformity in the application density of the imprint material 2 in the droplet pattern.

While the first to third embodiments each concern an optical imprinting method in which the imprint material 2, which is curable with light, is cured with the application of the ultraviolet light 4 thereto, the present invention is not limited to such an imprinting method. The imprint material 2 may be a material that is curable with any kind of electromagnetic radiation including light, or a material that is curable with heat.

### Article Manufacturing Method

A method of manufacturing an article (a semiconductor integrated-circuit device, a liquid-crystal-display device, an imaging device, a magnetic head, a compact disc rewritable (CD-RW), an optical device, a photomask, or the like) according to an embodiment of the present invention includes a step of forming a pattern on a substrate 3 (a monocrystalline silicon wafer, a silicon on insulator (SOI), a glass plate, or the like) by using the imprinting apparatus 1, and a step of performing at least one of etching and ion implantation on the substrate 3 having the pattern. The method may further include any known processing steps (oxidization, film formation, deposition, planarization, resist stripping, dicing, bonding, packaging, and so forth).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-074495, filed Mar. 31, 2015, which is hereby incorporated by reference herein in its entirety.

What is claimed is:

1. An imprinting apparatus that forms patterns sequentially on a plurality of areas of a substrate by using a mold and imprint material, the apparatus comprising:
a moving unit configured to be movable along a horizontal plane while carrying the substrate on which the imprint material is provided; and
an applying unit configured to apply the imprint material onto the substrate based on information related to a state of the imprint material and information related to an order of pattern formation, the information related to the state of the imprint material varying with the movement of the moving unit.

2. The apparatus according to claim 1, further comprising:
a creating unit configured to create data on a distribution of the imprint material to be applied onto the substrate, the creating unit creating the data from the information related to the state of the imprint material and the information related to the order of pattern formation,
wherein the applying unit applies the imprint material based on the data created by the creating unit.

3. The apparatus according to claim 1, wherein the information related to the order of pattern formation indicates an order of pattern formation performed on the plurality of areas.

4. The apparatus according to claim 2, wherein the creating unit creates the data based further on a direction of movement of the moving unit from a position facing the applying unit to a position facing the mold.

5. The apparatus according to claim 4,
wherein, among the plurality of areas, a first area on which the pattern is yet to be formed is on a leading side of the moving unit with respect to a second area on which the pattern has been formed,
wherein data created for one of the plurality of areas by the creating unit is first data indicating that an application density in the one area is higher on the leading side than on a trailing side that is opposite the leading side, and
wherein the applying unit applies the imprint material to the first area based on the first data.

6. An imprinting apparatus that forms a pattern on a substrate by using a mold and imprint material, the apparatus comprising:
a moving unit configured to be movable along a horizontal plane while carrying the substrate on which the imprint material is provided; and
an applying unit configured to apply the imprint material onto the substrate based on information related to a state of the imprint material and information related to a direction of movement of the moving unit, the information related to the state of the imprint material varying with the movement of the moving unit.

7. The apparatus according to claim 6 further comprising:
a creating unit configured to create data on a distribution of the imprint material to be applied onto the substrate, the creating unit creating the data from the information related to the state of the imprint material and the information related to the direction of movement of the moving unit,
wherein the applying unit applies the imprint material based on the data created by the creating unit.

8. The apparatus according to claim 6, wherein the direction of movement of the moving unit is a direction in which the moving unit moves from a position facing the applying unit to a position facing the mold.

9. The apparatus according to claim 7, wherein the data created by the creating unit indicates that an application density of the imprint material on an area of the substrate is lower on a leading side of the area than on a trailing side of the area that is opposite the leading side.

10. The apparatus according to claim 7, wherein the creating unit is configured to create the data based further on information related to a speed at which the moving unit moves along the horizontal plane.

11. A method of creating data on a distribution of imprint material that is applied onto a substrate when a pattern is formed on the substrate by using a mold and the imprint material, the method comprising:
acquiring information related to a variation in a state of the imprint material on the substrate, the variation occurring when the substrate moves; and
creating the data based on the information acquired.

12. A method of creating data on a distribution of imprint material that is applied onto a plurality of areas of a substrate when patterns are formed sequentially on the plurality of areas by using a mold and the imprint material, the method comprising:
acquiring information related to a state of the imprint material and information related to an order of pattern formation, the information related to the state of the imprint material varying with a movement of the substrate; and
creating the data based on the information acquired.

13. The method according to claim 12, further comprising:
acquiring a direction of movement of the substrate from a position facing an applying unit that applies the imprint material onto the substrate to a position facing the mold,
wherein the data is created based further on the direction of movement of the substrate acquired.

14. A method of creating data on a distribution of imprint material onto a plurality of areas of a substrate when patterns are formed sequentially on the plurality of areas by using a mold and the imprint material, the method comprising:
acquiring information related to a state of the imprint material and information related to a direction of movement of the substrate, the information related to the state of the imprint material varying with a movement of the substrate; and
creating the data based on the information acquired.

15. The method according to claim 14, wherein the direction of movement corresponds to a direction in which the substrate moves from a position facing an applying unit that applies the imprint material onto the substrate to a position facing the mold.

16. An imprinting method comprising:
applying imprint material onto a substrate based on data created by the method according to claim 11; and
forming a pattern on the substrate by using the mold and the imprint material applied onto the substrate.

17. An imprinting method comprising:
applying imprint material onto a substrate based on data created by the method according to claim 12; and
forming a pattern on the substrate by using the mold and the imprint material applied onto the substrate.

18. An article manufacturing method comprising:
forming a pattern on a substrate by the imprinting method according to claim 16; and
performing one of etching and ion implantation on the substrate having the pattern.

19. An article manufacturing method comprising:
forming a pattern on a substrate by the imprinting method according to claim 17; and
performing one of etching and ion implantation on the substrate having the pattern.
